(19) United States
(12) Patent Application Publication
(10) Pub. No.: US 2020/0135535 A1
(43) Pub. Date: Apr. 30, 2020

(54) TESTING TOOL FOR FLEXIBLE DISPLAY

(71) Applicant: INCOFLEX SEMICONDUCTOR TECHNOLOGY CO., LTD., SHAANXI (CN)

(72) Inventor: CHIACHEN LI, SHAANXI (CN)

(21) Appl. No.: 16/661,986

(22) Filed: Oct. 23, 2019

(30) Foreign Application Priority Data
Oct. 26, 2018 (CN) 201811261037.4
Oct. 26, 2018 (CN) 201811261067.5

(51) Int. Cl. H01L 21/687; G01N 3/20; G09F 9/30; H05K 1/18

(52) U.S. Cl. CPC H01L 21/68721; H01L 21/68728; H05K 2201/10128; G09F 9/301; H05K 1/189; G01N 3/20

(57) ABSTRACT

A testing tool for testing a flexible display includes a platform, a first mechanical component and a second mechanical component. The platform includes a plane. The first mechanical component is disposed on the plane to drive the flexible display to move, wherein the first mechanical component includes a first clamping unit connected to a first end of the flexible display. The second mechanical component is disposed on the plane opposite to the first mechanical component, wherein the second mechanical component includes a second clamping unit connected to a second end of the flexible display.

### TECHNICAL FIELD

The present disclosure relates to testing tools for flexible displays, and more particularly, to a testing tool for testing a rolled-up state and a folded state of a flexible display.

### BACKGROUND ART

Flexible displays are advantageous due to their compact size, power efficiency and durability, and therefore have great potential for widespread use as electronic visual displays, such as smartphone screens, computer displays, and full-color TV screens. Requirements for electrical performance and reliability of a flexible display operating in a rolled-up state or in a folded state are different from requirements when the flexible display is operating in a flat state; hence, reliability testing and durability testing are performed on a flexible display not only while the flexible display is operating in a flat state but also while the flexible display is operating in a rolled-up state and a folded state.

To test a flexible display's ability to be rolled up, a conventional testing tool is operated as follows: electrically connecting one end of the flexible display to a rolling motor; and connecting the other end of the flexible display to a terminal socket of a lighting jig. However, the terminal socket of the lighting jig cannot be rolled up. As a result, the rolling testing tool according to the prior art can roll up only one end of the flexible display. Thus, there is no flexibility in rolling of the conventional rolling testing tool. Furthermore, when testing the flexible display's ability to be folded, the conventional testing tool can attain only one angle of folding. Consequently, the conventional testing tool cannot perform folding testing in different modes in a single testing process.

### SUMMARY

The present disclosure provides a testing tool for testing a flexible display including a platform, a first mechanical component and a second mechanical component. The platform includes a plane. The first mechanical component is disposed on the plane to drive the flexible display to move, wherein the first mechanical component includes a first clamping unit connected to a first end of the flexible display. The second mechanical component is disposed on the plane opposite to the first mechanical component, wherein the second mechanical component includes a second clamping unit connected to a second end of the flexible display.

The present disclosure provides another testing tool for testing a flexible display including a platform, a first vertical movement component, a second vertical movement component and one or more middle support components. The platform includes a plane. The first vertical movement component is disposed on the plane and connected to a first end of the flexible display to vertically move the first end of the flexible display The second vertical movement component is disposed on the plane opposite to the first vertical movement component, and connected to a second end of the flexible display to vertically move the second end of the flexible display. The one or more middle support components is disposed on the plane and located between the first vertical movement component and the second vertical movement component to support the flexible display.

### BRIEF DESCRIPTION OF THE DRAWINGS

The accompanying drawings described below further illustrate the present disclosure without placing any limitations on the present disclosure.

FIG. 1 is a schematic view of a testing tool according to an embodiment of the present disclosure.

FIG. 2 is a schematic view of a flexible display and a flexible circuit board, which are connected according to an embodiment of the present disclosure.

FIG. 3 is a schematic view of a first clamping unit and a second clamping unit, which clamp the flexible display according to an embodiment of the present disclosure.

FIG. 4 is a schematic view of the first clamping unit according to an embodiment of the present disclosure.

FIG. 5 is a schematic view of the flexible display rolled up by the testing tool according to an embodiment of the present disclosure.

FIG. 6 is a schematic view of the flexible display rolled up and folded by the testing tool according to an embodiment of the present disclosure.

FIG. 7 is a schematic view of the first clamping unit and the second clamping unit, which clamp the flexible display according to a variant embodiment of the present disclosure.

FIG. 8 is a schematic view of the testing tool according to an embodiment of the present disclosure.

FIG. 9 is a schematic view of the flexible display rolled up by the testing tool according to an embodiment of the present disclosure.

FIG. 10 is a schematic view of the flexible display folded upward by the testing tool according to an embodiment of the present disclosure.

FIG. 11 is a schematic view of the flexible display folded downward by the testing tool according to an embodiment of the present disclosure.

FIG. 12 is a schematic view of the flexible display rolled up by the testing tool according to an embodiment of the present disclosure.

FIG. 13 is a schematic view of the flexible display folded by the testing tool to take on a Z-shaped form according to an embodiment of the present disclosure.

### EMBODIMENTS

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to +4°, less than or equal to ±3°, less than or equal to ±2°, less than or equal to +1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

As used herein, the terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a tool, a system, a device, or an apparatus that “comprises,” “has,” “includes” or “contains” one or more elements possesses those one or more elements, but is not limited to possessing only those one or more elements. Likewise, an element of a tool, a system, a device, or an apparatus that “comprises,” “has,” “includes” or “contains” one or more features possesses those one or more features, but is not limited to possessing only those one or more features.

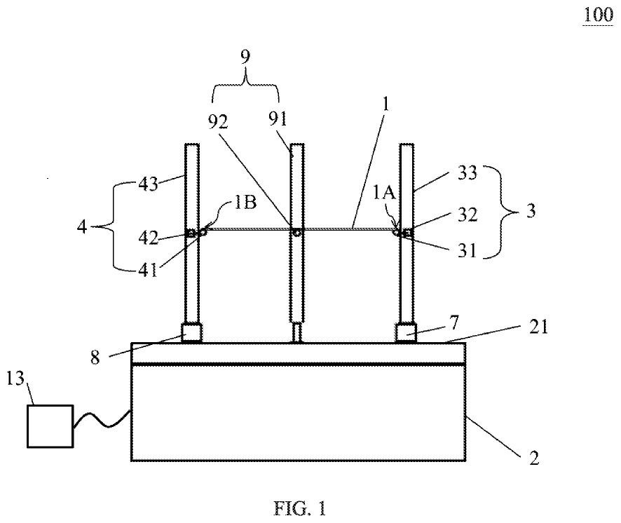

Referring to FIG. 1, FIG. 1 is a schematic view of a testing tool according to an embodiment of the present disclosure. In the embodiment of the present disclosure, the testing tool 100 is configured to test a flexible display 1. The testing tool 100 includes a platform 2, a first mechanical component 3 and a second mechanical component 4. As shown in FIG. 1, the platform 2 includes a plane 21 for supporting the first mechanical component 3 and the second mechanical component 4. The platform 2 may be either a rectangular box or a supportive structure composed of a flat board and a plurality of support rods disposed under the flat board, but the present disclosure is not limited thereto. The platform 2 may also be any other appropriate platform structure selected in accordance with the actual testing situation. The first mechanical component 3 is disposed on the plane 21 and configured to drive the flexible display 1 to move. The first mechanical component 3 may include a first clamping unit 31 for connecting the first mechanical component 3 to a first end 1A of the flexible display 1 and rolling up the first end 1A of the flexible display 1. The second mechanical component 4 is disposed on the plane 21 and located opposite to the first mechanical component 3. The second mechanical component 4 may include a second clamping unit 41 for connecting to and clamping a second end 1B of the flexible display 1.

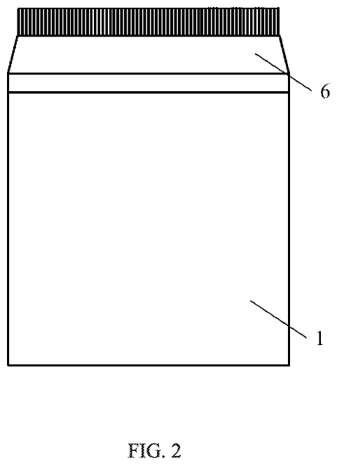

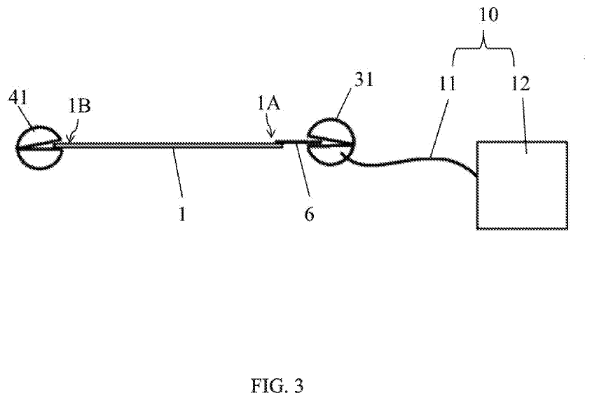

Referring to FIGS. 2 to 3, FIG. 2 is a schematic view of a flexible display and a flexible circuit board, which are connected according to the present disclosure, and FIG. 3 is a schematic view of a first clamping unit 31 and a second clamping unit 41, which clamp the flexible display according to an embodiment of the present disclosure. In some embodiments, the first end 1A of the flexible display 1 is connected to a flexible circuit board 6. The first clamping unit 31 may be configured to clamp the flexible circuit board 6 to connect the first clamping unit 31 to the first end 1A of the flexible display 1.

As shown in FIG. 3, the testing tool 100 may further include a lighting module 10. The lighting module 10 is electrically connected to the flexible circuit board 6 through the first clamping unit 31. The lighting module 10 lights up the flexible display 1 through the first clamping unit 31 and the flexible circuit board 6. In some embodiments, the lighting module 10 may further include a signal line 11 and a signal controller 12. One end of the signal line 11 may pass through a side of the first clamping unit 31 to connect the signal line 11 to the flexible circuit board 6. The other end of the signal line 11 may be connected to the signal controller 12. The signal controller 12 sends a signal to the flexible display 1 through the signal line 11 and the flexible circuit board 6 to light up the flexible display 1 and thereby test the flexible display 1. The signal enables images or animations to be displayed on the flexible display 1, but the present disclosure is not limited thereto.

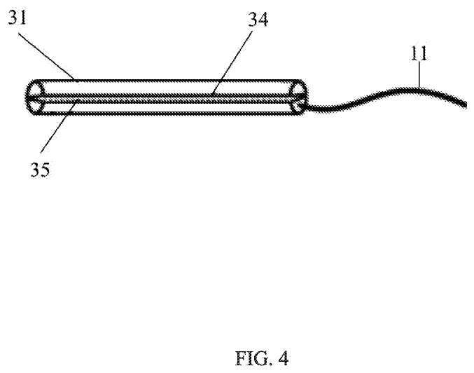

Referring to FIG. 4, FIG. 4 is a schematic view of the first clamping unit 31 according to an embodiment of the present disclosure. In some embodiments, the first clamping unit 31 may include a cylindrical structure. The first clamping unit 31 includes an opening 34 extending in an axial direction for clamping the flexible circuit board 6. The opening 34 may include a plurality of probes 35. The plurality of probes 35 are inserted into the flexible circuit board 6 such that the flexible circuit board 6 is electrically connected to the first clamping unit 31. The cylindrical first clamping unit 31 clamping the flexible circuit board 6 is rotated to roll up the flexible circuit board 6 and thereby roll up the flexible display 1.

In the present embodiment, the first clamping unit 31 includes a cylindrical structure and is configured to roll up the flexible display 1, but the present disclosure is not limited thereto. The first clamping unit 31 may include any other appropriate shape. For example, the first clamping unit 31 may be curved or rod-shaped in order to roll up the flexible display 1.

In general, if the flexible circuit board 6 is inserted into a terminal socket of a lighting jig, the flexible display 1 at the corresponding end cannot be rolled up because the terminal socket of the lighting jig cannot be rolled up. According to the present disclosure, the flexible circuit board 6 is clamped by the first clamping unit 31. With the first clamping unit 31 including a cylindrical structure, the flexible display 1 at the corresponding end can be rolled up relative to the first clamping unit 31.

Referring to FIG. 1 again, in some embodiments, the first mechanical component 3 may include a first rolling unit 32. The first rolling unit 32 connects to the first clamping unit 31. The first rolling unit 32 rolls the first clamping unit 31 forward or backward and thereby rolls up or unrolls the flexible display 1. The first rolling unit 32 may include a first forward/backward servo motor (not shown in the drawings). The first forward/backward servo motor connects to the first clamping unit 31. The first forward/backward servo motor drives the first clamping unit 31 to roll up or unroll the flexible display 1.

In some embodiments, the first mechanical component 3 further includes a first vertical movement unit 33. The first vertical movement unit 33 drives the flexible display 1 to move vertically. The first vertical movement unit 33 connects to the first end 1A of the flexible display 1 through the first clamping unit 31. The first vertical movement unit 33 drives the first clamping unit 31 to move vertically so as to drive the flexible display 1 to move vertically. According to the present disclosure, the first vertical movement unit 33 may be, for example, a motor and ball bearing screw, but the present disclosure is not limited thereto.

The second mechanical component 4 includes the second clamping unit 41. The second clamping unit 41 clamps the second end 1B of the flexible display 1 and rolls up the flexible display 1. In some embodiments, both the second clamping unit 41 and the first clamping unit 31 are cylindrical. Similarly, the second clamping unit 41 may include an opening extending in an axial direction not only for clamping the flexible circuit board 6 but also for clamping the second end 1B of the flexible display 1, but the present disclosure is not limited thereto. The second clamping unit 41 may have other appropriate structures.

In some embodiments, the second mechanical component 4 may include a second rolling unit 42. The second rolling unit 42 connects to the second clamping unit 41. The second rolling unit 42 rolls the second clamping unit 41 forward or backward so as to roll up or unroll the flexible display 1. The second rolling unit 42 may include a second forward/backward servo motor (not shown in the drawings). The second forward/backward servo motor connects to the second clamping unit 41. The second forward/backward servo motor rolls up or unrolls the flexible display 1 through the second clamping unit 41.

The second mechanical component 4 may further include a second vertical movement unit 43. The second vertical movement unit 43 drives the flexible display 1 to move vertically. The second vertical movement unit 43 connects to the second end 1B of the flexible display 1 through the second clamping unit 41. The second vertical movement unit 43 drives the second clamping unit 41 to move vertically so as to drive the flexible display 1 to move vertically. According to the present disclosure, the second vertical movement unit 43 may be, for example, a motor and ball bearing screw, but the present disclosure is not limited thereto.

Alternatively, the testing tool 100 may further include a middle support component 9. The middle support component 9 is disposed on the plane 21 and located between the first mechanical component 3 and the second mechanical component 4. The middle support component 9 supports the flexible display 1 when the two ends of the flexible display 1 move vertically, thereby allowing the flexible display 1 to be folded.

For example, when the first vertical movement unit 33 and the second vertical movement unit 43 drive two ends of the flexible display 1 to move upward, the middle support component 9 is positioned over the flexible display 1 and in contact with the flexible display 1 such that the flexible display 1 folds upward. Accordingly, the testing tool 100 allows the rolling testing to be performed on the flexible display 1 in the upward folded state.

When the first vertical movement unit 33 and the second vertical movement unit 43 drive two ends of the flexible display 1 to move downward, the middle support component 9 is positioned under the flexible display 1 and in contact with the flexible display 1 such that the flexible display 1 folds downward. Accordingly, the testing tool 100 allows the rolling testing to be performed on the flexible display 1 in the downward folded state.

As shown in FIG. 1, the middle support component 9 may further include support rods 91 and a third vertical movement unit 92. The support rods 91 are disposed under or over the flexible display 1. The support rods 91 support the flexible display 1. The third vertical movement unit 92 connects to the support rods 91 to drive the middle of the flexible display 1 to move vertically so as to fold the flexible display 1. According to the present disclosure, the third vertical movement unit 92 may be, for example, a motor and ball bearing screw, but the present disclosure is not limited thereto.

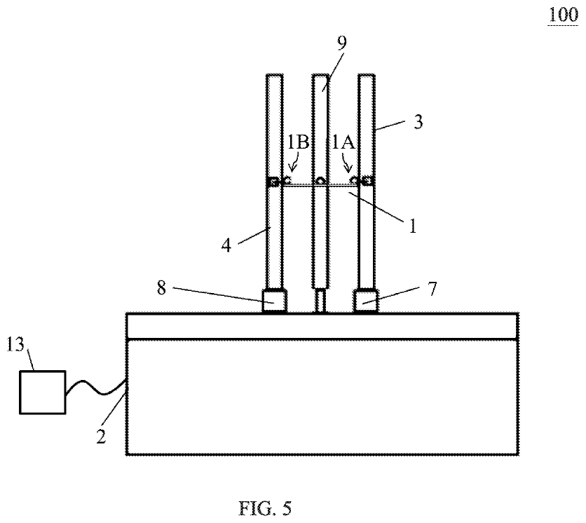

Referring to FIG. 5, FIG. 5 is a schematic view of the flexible display 1 rolled up by the testing tool according to an embodiment of the present disclosure. According to the present disclosure, the testing tool 100 uses the first and second forward/backward servo motors to respectively drive the first clamping unit 31 and the second clamping unit 41 to roll up and unroll the flexible display 1. The testing tool 100 uses the signal controller 12 to send a signal to the flexible display 1 and thereby light up the flexible display 1. Accordingly, the testing tool 100 allows testing to be performed on the flexible display 1 in the rolled-up state or the unrolled state.

When the first clamping unit 31 rolls up the flexible display 1, and the second clamping unit 41 rolls up the flexible display 1, testing can be performed on the flexible display 1 with two ends rolled up. When the first clamping unit 31 unrolls the flexible display 1, and the second clamping unit 41 unrolls the flexible display 1, testing can be performed on the flexible display 1 with two ends unrolled.

When the first clamping unit 31 rolls up the flexible display 1 and the second clamping unit 41 unrolls the flexible display 1, or when the first clamping unit 31 unrolls the flexible display 1 and the second clamping unit 41 rolls up the flexible display 1, testing can be performed on the flexible display I with one end rolled up and the other end unrolled.

Furthermore, the first vertical movement unit 33 of the first mechanical component 3 and the second vertical movement unit 43 of the second mechanical component 4 may drive the flexible display 1 to move vertically such that testing may be performed on the flexible display 1 in the folded and rolled-up state.

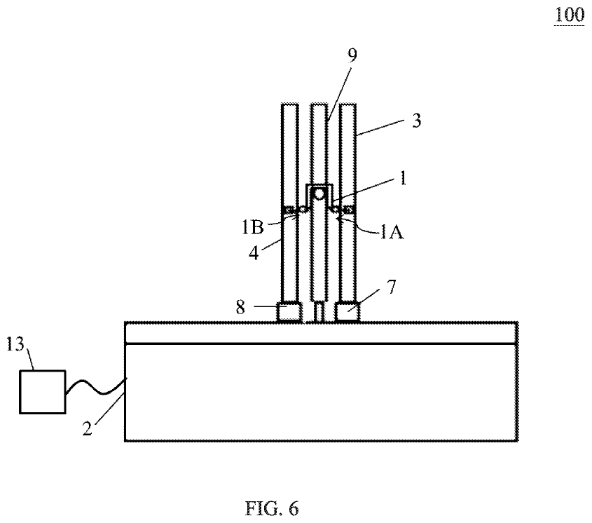

As shown in FIG. 6, FIG. 6 is a schematic view of the flexible display rolled up and folded by the testing tool according to an embodiment of the present disclosure. The first vertical movement unit 33 drives the first end 1A of the flexible display 1 to move downward through the first clamping unit 31. The first rolling unit 32 drives the first clamping unit 31 to rotate such that the first end 1A of the flexible display 1 is rolled up. The second vertical movement unit 43 and the second clamping unit 31 drive the second end 1B of the flexible display 1 to move downward, and the second rolling unit 42 drives the second clamping unit 41 to rotate such that the second end 1B of the flexible display 1 is rolled up. The middle support component 9 is positioned under the flexible display 1 and in contact with the flexible display 1. The testing tool 100 drives the flexible display 1 to fold downward. Therefore, the testing tool 100 allows the rolling testing to be performed on the flexible display 1 folded downward. The signal controller 12 sends a signal to the flexible display 1 through the first clamping unit 31 and lights up the flexible display 1. Thus, testing can be performed on the flexible display 1 in the folded and rolled-up state.

The sequence of operations of the first mechanical component 3 and the second mechanical component 4 is not limited to the aforementioned description, and the sequence of operation of the first mechanical component 3 and the second mechanical component 4 is subject to changes in accordance with the required folded and rolled-up state of the flexible display 1 in the course of the testing. Furthermore, the first mechanical component 3 and the second mechanical component 4 may roll up or fold the flexible display 1 separately or simultaneously, and the present disclosure is not restrictive of whether the rolling precedes or follows the folding. For example, the first mechanical component 3 rolls up the flexible display 1 or moves the flexible display 1 vertically, and then the second mechanical component 4 rolls up the flexible display 1 or moves the flexible display 1 vertically, but the present disclosure is not limited thereto. In a variant embodiment, both the first mechanical component 3 and the second mechanical component 4 roll up or vertically move the flexible display 1 simultaneously.

Referring to FIGS. 5 and 6, the testing tool 100 may further include a first horizontal movement component 7. The first horizontal movement component 7 is disposed on plane 21. The first horizontal movement component 7 drives the first mechanical component 3 to undergo a horizontal reciprocating movement in response to variations in the length of the rolled-up and folded flexible display 1. The first mechanical component 3 and the second mechanical component 4 move horizontally in order to drive the flexible display 1 to be rolled up or move vertically. The first horizontal movement component 7 connects to the first mechanical component 3 in order to drive the first mechanical component 3 to undergo a horizontal reciprocating movement relative to the plane 21. The first horizontal movement component 7 may be, for example, a motor and ball bearing screw, but the present disclosure is not limited thereto.

The testing tool 100 may further include a second horizontal movement component 8. The second horizontal movement component 8 is disposed on the plane 21. The second horizontal movement component 8 drives the second mechanical component 4 to undergo a horizontal reciprocating movement in response to variations in the length of the rolled-up or folded flexible display 1. The second horizontal movement component 8 connects to the second mechanical component 4 so as to drive the second mechanical component 4 to undergo a horizontal reciprocating movement relative to the plane 21. The second horizontal movement component 8 may be, for example, a motor and ball bearing screw, but the present disclosure is not limited thereto.

The testing tool 100 may further include a control unit 13. The control unit 13 controls the first mechanical component 3 and the second mechanical component 4. The control unit 13 electrically connects to the first mechanical component 3 and the second mechanical component 4 so as to control the first mechanical component 3 and the second mechanical component 4 to roll or move.

The testing tool of the present disclosure is not limited to the above-mentioned embodiments, and may include other different embodiments. To simplify the description and for the convenience of comparison between each of the embodiments of the present disclosure, the identical components in each of the following embodiments are marked with identical numerals. For making it easier to compare the difference between the embodiments, the following description will detail the dissimilarities among different embodiments and the identical features will not be redundantly described.

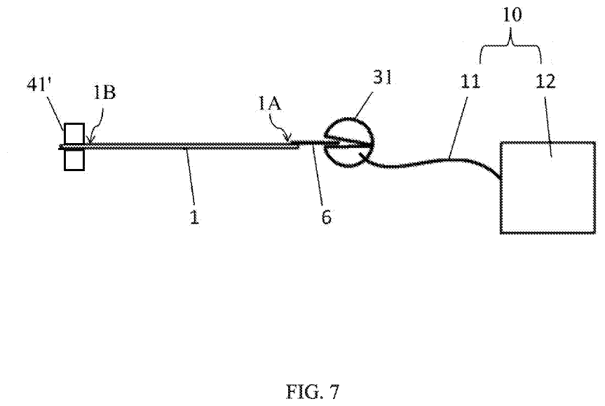

Referring to FIG. 7, FIG. 7 is a schematic view of the first clamping unit and the second clamping unit, which clamp the flexible display according to a variant embodiment of the present disclosure. In this embodiment, the second mechanical component 4 does not include the second rolling unit 42, and the second clamping unit 41′ does not roll up the second end 1B of the flexible display 1. Accordingly, testing can be performed with one end of the flexible display 1 being folded and the other end of the flexible display 1 being rolled up.

The second clamping unit 41′ may include two clamping blocks disposed vertically symmetrical to each other. The second end 1B of the flexible display 1 is clamped by and between the two clamping blocks. Therefore, the second clamping unit 41′ clamps and fixes the flexible display 1 in place, using the two clamping blocks. The second clamping unit 41′ clamps the flexible display 1 such that the second vertical movement unit 42 drives the second clamping unit 41 to move so as to drive the flexible display 1 to move vertically. The second clamping unit 41 may be, for example, a clamp, but the present disclosure is not limited thereto.

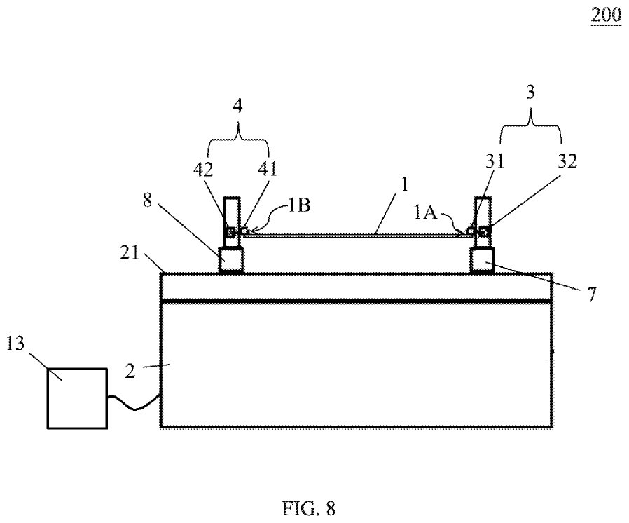

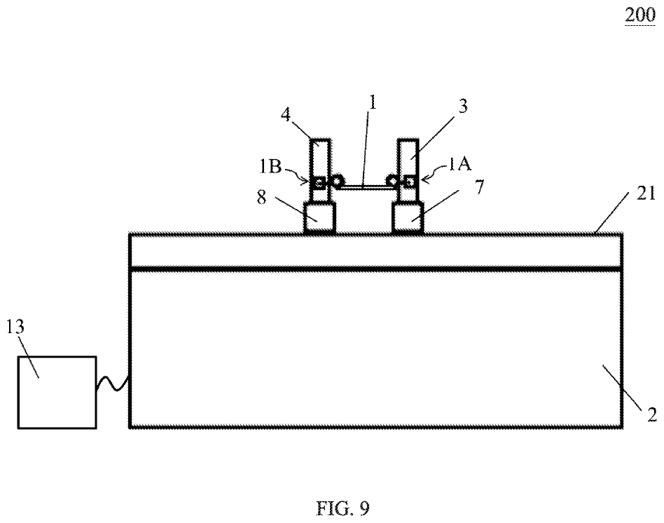

Referring to FIGS. 8 and 9, FIG. 8 is a schematic view of the testing tool 200 according to an embodiment of the present disclosure, and FIG. 9 is a schematic view of the flexible display rolled up by the testing tool according to an embodiment of the present disclosure. In the present embodiment, the testing tool 200 does not include the middle support component 9, the first mechanical component 3 does not include the first vertical movement unit 33, and the second mechanical component 4 does not include the second vertical movement unit 43. Therefore, the first mechanical component 3 only includes the first clamping unit 31 and the first rolling unit 32, whereas the second mechanical component 4 only includes the second clamping unit 41 and the second rolling unit 42.

Given the aforementioned configurations and arrangements, the testing tool 200 can perform testing on the flexible display 1 in three states as follows: two ends of the flexible display 1 are rolled up; two ends of the flexible display 1 are unrolled; and one end of the flexible display 1 is rolled up but the other end of the flexible display 1 is unrolled.

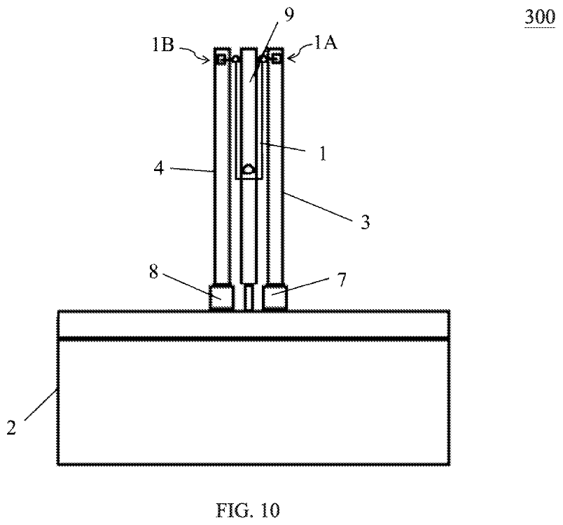

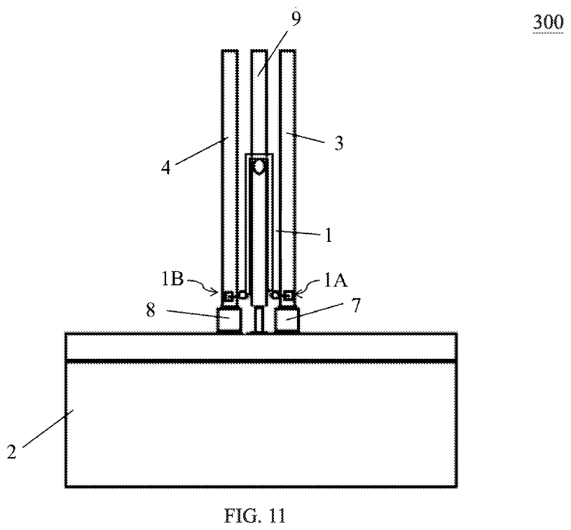

Referring to FIGS. 10 and 11, FIG. 10 is a schematic view of the flexible display folded upward by a testing tool 300 according to an embodiment of the present disclosure, and FIG. 11 is a schematic view of the flexible display folded downward by the testing tool 300 according to an embodiment of the present disclosure. In this embodiment, the testing tool 300 does not include any rolling units, that is, the first mechanical component 3 does not include the first rolling unit 32, and the second mechanical component 4 does not include the second rolling unit 42. Therefore, the first mechanical component 3 is a first vertical movement component, including the first clamping unit 31 and the first vertical movement unit 33 only, and drives the first end 1A of the flexible display 1 to move vertically. The second mechanical component 4 is a second vertical movement component, including the second clamping unit 41 and the second vertical movement unit 43 only, and drives the second end 1B of the flexible display 1 to move vertically.

As shown in FIG. 10, the middle support component 9 is disposed on the plane 21 and located between the first mechanical component 3 and the second mechanical component 4. When the first mechanical component 3 and the second mechanical component 4 drive two ends of the flexible display 1 to move upward, the middle support component 9 is positioned over the flexible display 1 and in contact with the flexible display 1 such that the flexible display 1 is folded upward. Accordingly, folding testing can be performed on the flexible display 1 with the flexible display 1 folded upward.

As shown in FIG. 11, when the first mechanical component 3 and the second mechanical component 4 drive two ends of the flexible display 1 to move downward, the middle support component 9 is positioned under the flexible display 1 and in contact with the flexible display 1 such that the flexible display 1 is folded downward. Accordingly, folding testing can be performed on the flexible display 1 with the flexible display 1 folded downward. Given the aforementioned configurations and arrangements, the testing tool 300 can perform folding testing on the flexible display 1 with the flexible display 1 folded upward and folded downward.

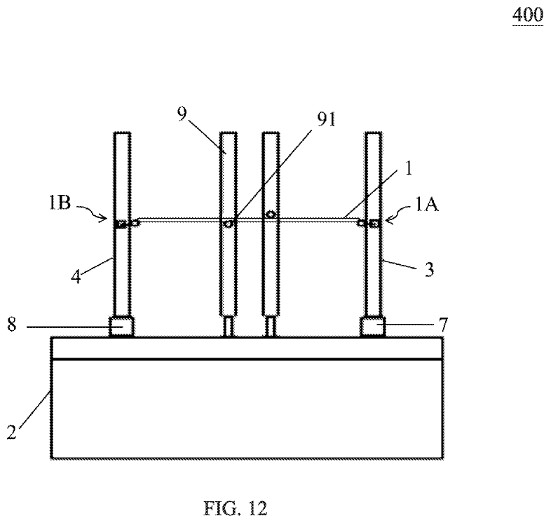

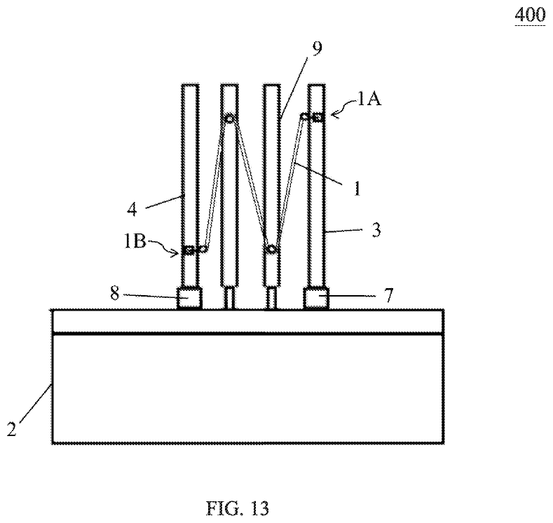

Referring to FIGS. 12 and 13, FIG. 12 is a schematic view of the flexible display rolled up by a testing tool 400 according to an embodiment of the present disclosure, and FIG. 13 is a schematic view of the flexible display folded by the testing tool into a Z-shaped form according to an embodiment of the present disclosure. Unlike the testing tool 100, the testing tool 400 includes two middle support components 9.

As shown in FIG. 12, the two middle support components 9 are disposed on the plane 21, located between the first mechanical component 3 and the second mechanical component 4, and spaced apart. The support rods 91 of one of the middle support components 9 are positioned under the flexible display 1. The support rods 91 of the other middle support component 9 are positioned over the flexible display 1. The arrangement of two middle support components 9 is not limited thereto. For example, the support rods 91 of the two middle support components 9 may be positioned simultaneously over and under the flexible display 1. Thus, testing can be performed on the flexible display 1 in other folded states.

As shown in FIG. 13, when the first mechanical component 3 and the second mechanical component 4 respectively drive two ends of the flexible display 1 to move upward and move downward, the two middle support components 9 drive two intermediate points of the flexible display 1 to move vertically but in opposite directions, respectively, such that the flexible display 1 is folded into a Z-shaped form. Accordingly, the folding testing can be performed on the flexible display 1 with the flexible display 1 folded into the Z-shaped form.

In a variant embodiment, the quantity of the middle support components 9 may be altered according to the folded state required for the testing. For example, when the quantity of middle support components 9 is two or more, the testing tool 400 includes a plurality of middle support components 9 disposed on the plane 21, located between the first mechanical component 3 and the second mechanical component 4, and spaced apart. Thus, testing can be performed on the flexible display 1 in the required folded state.

The testing tool of the present disclosure includes advantages over the prior art because of technical features of the testing tool as follows:

1. A first clamping unit of a first mechanical component and a second clamping unit of a second mechanical component drive two ends of a flexible display to be rolled up, thereby allowing testing to be performed on the flexible display with its two ends rolled up;

2. A forward/backward servo motor drives the flexible display to be rolled up and unrolled, thereby allowing testing to be performed on the flexible display in the rolled-up state and the unrolled state;

3. A first vertical movement unit of the first mechanical component, a second vertical movement unit of the second mechanical component, and a middle support component together allow testing of the flexible display while the flexible display is folded upward and downward;

4. With a plurality of middle support components, a plurality of third vertical movement units drive the middle of the flexible display to move vertically, while the first vertical movement unit and the second vertical movement unit drive two ends of the flexible display to move vertically, thereby allowing testing to be performed on the flexible display folded in various ways; and

5. The first vertical movement unit, the second vertical movement unit, and the middle support components drive the flexible display to be folded, and the forward/backward servo motors drive the flexible display to be rolled up and unrolled, thereby allowing testing to be performed on the flexible display in folded and rolled-up states simultaneously.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A testing tool for testing a flexible display, the testing tool comprising:
a platform comprising a plane;
a first mechanical component disposed on the plane to drive the flexible display to move, wherein the first mechanical component comprises a first clamping unit connected to a first end of the flexible display ; and
a second mechanical component disposed on the plane opposite to the first mechanical component, wherein the second mechanical component comprises a second clamping unit connected to a second end of the flexible display.

2. The testing tool of claim 1, further comprising a control unit electrically connected to the first mechanical component and the second mechanical component, wherein the control unit is configured to control the first mechanical component and the second mechanical component.

3. The testing tool of claim 1, wherein the first mechanical component further comprises a first forward/backward servo motor connected to the first clamping unit to drive the first clamping unit to roll up or unroll the flexible display.

4. The testing tool of claim 1, wherein the first end of the flexible display is connected to a flexible circuit board.

5. The testing tool of claim 4, wherein the first clamping unit is configured to clamp the flexible circuit board to connect the first clamping unit to the first end of the flexible display.

6. The testing tool of claim 5, wherein the first clamping unit comprises a cylindrical structure to roll up the flexible display, the first clamping unit comprises an opening extending in an axial direction configured to clamp the flexible circuit board, a plurality of probes are disposed in the opening, and the flexible circuit board is electrically connected to the first clamping unit by inserting the plurality of probes into the flexible circuit board.

7. The testing tool of claim 4, further comprising a lighting module electrically connected to the flexible circuit board through the first clamping unit and configured to light up the flexible display through the first clamping unit and the flexible circuit board.

8. The testing tool of claim 7, in the lighting module further comprises:
a signal line with an end passing through a side of the first clamping unit to connect the signal line to the flexible circuit board; and
a signal controller connected to another end of the signal line and configured to light up the flexible display through the signal line and the flexible circuit board.

9. The testing tool of claim 1, wherein the second clamping unit is configured to clamp the second end of the flexible display and roll up the flexible display.

10. The testing tool of claim 9, wherein the second mechanical component further comprises a second forward/backward servo motor connected to the second clamping unit to drive the second clamping unit to roll up or unroll the flexible display.

11. The testing tool of claim 1, wherein the second clamping unit further comprises two clamping blocks disposed vertically symmetrical to each other and configured to clamp the second end of the flexible display.

12. The testing tool of claim 1, further comprising a first horizontal movement unit disposed on the plane, wherein the first horizontal movement unit is connected to the first mechanical component and configured to drive the first mechanical component to move horizontally and reciprocating relative to the plane.

13. The testing tool of claim 12, further comprising a second horizontal movement unit disposed on the plane, wherein the second horizontal movement unit is connected to the second mechanical component and configured to drive the second mechanical component to move horizontally and reciprocating relative to the plane.

14. The testing tool of claim 1, wherein the first mechanical component further comprises a first vertical movement unit configured to drive the flexible display to move vertically, wherein the first vertical movement unit is connected to the first clamping unit to connect the first vertical movement unit to the first end of the flexible display.

15. The testing tool of claim 14, wherein the second mechanical component further comprises a second vertical movement unit configured to drive the flexible display to move vertically, wherein the second vertical movement unit is connected to the second clamping unit to connect the second vertical movement unit to the second end of the flexible display.

16. The testing tool of claim 15, further comprising:
one or more middle support components disposed on the plane and located between the first mechanical component and the second mechanical component, wherein the one or more middle support components is configured to support the flexible display,
wherein a first middle support component of the one or more middle support components is positioned over the flexible display and in contact with the flexible display such that the flexible display is folded upward when the first vertical movement unit and the second vertical movement unit drive the first end and the second end of the flexible display to move upward, additionally or alternatively a second middle support component of the one or more middle support components is positioned under the flexible display and in contact with the flexible display such that the flexible display is folded downward when the first vertical movement unit and the second vertical movement unit drive the first end and the second end of the flexible display to move downward.

17. The testing tool of claim 16, wherein the one or more middle support components further comprises support rods and a third vertical movement unit, the support rods are disposed under or over the flexible display to support the flexible display, and the third vertical movement unit is connected to the support rods to drive a middle of the flexible display to move vertically and fold the flexible display.

18. The testing tool of claim 17, wherein the support rods of one of the first middle support component are positioned under the flexible display, and the support rods of the second middle support component are positioned over the flexible display, wherein the first and second middle support components drive two intermediate points of the flexible display to move vertically but in opposite directions such that the flexible display is folded into a Z-shaped form when the first vertical movement unit and the second vertical movement unit drive the first end and the second end of the flexible display to move upward and move downward, respectively.

19. A testing tool for testing a flexible display, the testing tool comprising:
a platform comprising a plane;
a first vertical movement component disposed on the plane and connected to a first end of the flexible display to vertically move the first end of the flexible display;
a second vertical movement component, disposed on the plane opposite to the first vertical movement component, and connected to a second end of the flexible display to vertically move the second end of the flexible display; and
one or more middle support components, disposed on the plane and located between the first vertical movement component and the second vertical movement component to support he flexible display.

20. The testing tool of claim 19, wherein one of the one or more middle support components is positioned over the flexible display and in contact with the flexible display to allow the flexible display to fold upward when the first vertical movement component and the second vertical movement component drive the first end and the second end of the flexible display to move upward, additionally or alternatively another one of the one or more middle support components is positioned under the flexible display and in contact with the flexible display to allow the flexible display to fold downward when the first vertical movement component and the second vertical movement component drive the first end and the second end of the flexible display to move downward.
